(19) United States
(12) Patent Application Publication
(10) Pub. No.: US 2025/0218825 A1
(43) Pub. Date: Jul. 3, 2025

(54) SUBSTRATE PROCESSING APPARATUS

(71) Applicant: SEMES CO., LTD., Cheonan-si (KR)

(72) Inventor: Jae Woo KIM, Cheonan-si (KR)

(73) Assignee: SEMES CO., LTD., Cheonan-si (KR)

(21) Appl. No.: 19/004,421

(22) Filed: Dec. 29, 2024

(30) Foreign Application Priority Data
Dec. 29, 2023 (KR) 10-2023-0197014

(51) Int. Cl. H01L 21/67; H01J 37/32; H01L 21/687

(52) U.S. Cl. CPC H01L 21/67248; H01J 37/3244; H01J 37/32724; H01L 21/68785; H01J 2237/002; H01J 2237/2007; H01J 2237/24585

(57) ABSTRACT

Proposed is a substrate processing apparatus including a process chamber configured to provide a substrate processing space, a substrate chuck configured to support a substrate in the substrate processing space, have a heater, and control temperature of the substrate, and a chuck temperature control unit configured to divide the substrate chuck into a plurality of heating areas and regulate temperature of the substrate chuck by heating area through heat absorption, heat shielding, and cooling.

### CROSS REFERENCE TO RELATED APPLICATION

The present application claims priority to Korean Patent Application No. 10-2023-0197014, filed Dec. 29, 2023, the entire contents of which is incorporated herein for all purposes by this reference.

### BACKGROUND OF THE INVENTION

### Field of the Invention

The present disclosure relates to a substrate processing apparatus used to process substrates such as wafers and, more particularly, to a substrate processing apparatus including a substrate chuck capable of controlling the temperature of a substrate.

### Description of the Related Art

To manufacture semiconductors, various substrate processing processes need to be performed, and to perform a substrate processing process, a substrate processing apparatus should be used.

Typically, a substrate processing apparatus includes a substrate chuck that supports a substrate while a substrate processing process is carried out. The substrate chuck includes a heater to heat the substrate and maintain the temperature of the substrate at the temperature required for the substrate processing process.

The substrate chuck may be heated by the heater, and the heat from the heater may be transferred to the substrate through the substrate chuck. In order to prevent problems such as poor processing and reduced process efficiency due to temperature differences between regions of a substrate, the heater is configured to divide the substrate chuck into a plurality of regions and heat the substrate chuck for each region.

If the substrate chuck is divided into a relatively small number of regions and heated for each region, it is difficult to precisely control the temperature distribution of the substrate chuck, and the temperature distribution of the substrate chuck is bound to become non-uniform. On the other hand, dividing the substrate chuck into a relatively large number of regions and heating each region would be advantageous in terms of uniformizing the temperature distribution of the substrate chuck, but the problem is that the structure of the heater is complicated and installation of the heater is difficult, which is inevitably disadvantageous in terms of manufacturing the substrate chuck. Therefore, there is a need to prepare improvement measures for this.

### DOCUMENTS OF RELATED ART

(Patent Document 0001) Korean Patent Application Publication No. 10-2005-0109132 (Nov. 17, 2005)

(Patent Document 0002) Korean Patent Application Publication No. 10-2021-0144333 (Nov. 30, 2021)

### SUMMARY OF THE INVENTION

Accordingly, the present disclosure has been made keeping in mind the above problems occurring in the related art, and the present disclosure is intended to provide a substrate processing apparatus capable of heating a substrate uniformly with a simple configuration when processing the substrate.

The objectives to be achieved are not limited to this, and other objectives not mentioned can be clearly understood by those skilled in the art from the following description.

In order to achieve the above objectives, according to an embodiment of the present disclosure, there is provided a substrate processing apparatus including: a process chamber configured to provide a substrate processing space; a substrate chuck configured to support a substrate in the substrate processing space, have a heater, and control temperature of the substrate; and a heat absorbing plate provided on a lower surface of the substrate chuck and configured to adjust temperature of the substrate chuck by absorbing heat from the substrate chuck, wherein the heat absorbing plate may be composed of a plurality of heat absorbing blocks divided to absorb the heat by heating area by dividing the substrate chuck into a plurality of heating areas, wherein the heat absorbing blocks may be selectively removed on the basis of temperature of each of the heating areas. The plurality of heat absorbing blocks may be a heat sink.

The substrate processing apparatus according to an embodiment of the present disclosure may further include a heat shielding plate provided on a lower surface of the heat absorbing plate, wherein the heat shielding plate may be composed of a plurality of heat shielding blocks divided to block heat transfer by the heating area, wherein the heat shielding blocks may be selectively removed on the basis of the temperature of each of the heating areas.

The substrate processing apparatus according to an embodiment of the present disclosure may further include a nozzle block configured to spray a cooling gas upward from below the heat shielding plate. The cooling gas may be an inert gas. The cooling gas may be nitrogen (N2).

The substrate chuck may be spaced upward from a bottom of the substrate processing space, and the nozzle block may be disposed on a bottom side of the substrate processing space.

The cooling gas sprayed upward from the nozzle block may collide with a lower surface of the heat shielding plate and flow to a side wall of the process chamber, and the process chamber may be provided with an exhaust port on a side wall thereof.

The substrate processing apparatus according to an embodiment of the present disclosure may further include a chuck temperature detector configured to detect the temperature for each of the heating areas.

The substrate processing apparatus may perform ashing as a substrate processing process.

The heat absorbing blocks may be in contact with the lower surface of the substrate chuck to absorb the heat conducted from the substrate chuck. For example, the heat absorbing blocks may include aluminum nitride (AIN) material with excellent heat conductivity.

According to an embodiment of the present disclosure, there may be provided a substrate processing apparatus including: a process chamber configured to provide a substrate processing space; a substrate chuck configured to support a substrate in the substrate processing space, have a heater, and control temperature of the substrate; and a chuck temperature control unit configured to divide the substrate chuck into a plurality of heating areas and adjust temperature of the substrate chuck for each of the heating areas using a temperature control gas.

The chuck temperature control unit may include a nozzle block configured to spray the temperature control gas upward from below the substrate chuck. The nozzle block may be configured to spray the temperature control gas for each of the heating areas. The nozzle block may receive the temperature control gas from a gas supply module and spray the received temperature control gas. The gas supply module may include a heater for heating the temperature control gas and a cooler for cooling the temperature control gas, and may supply the temperature control gas heated by the heater or supplies the temperature control gas cooled by the cooler on the basis of temperature of each of the heating areas.

Alternatively, the chuck temperature control unit may include: a heat shielding plate provided below the substrate chuck; and a nozzle block configured to spray the cooling gas upward from below the heat shielding plate, wherein the heat shielding plate may be composed of a plurality of heat shielding blocks divided to block heat transfer by the heating area, wherein the heat shielding blocks may be selectively removed on a basis of temperature of each of the heating areas.

According to an embodiment of the present disclosure, there may be provided a substrate processing apparatus including: a process chamber configured to provide a substrate processing space; a substrate chuck configured to support a substrate in the substrate processing space, spaced upward from the bottom of the substrate processing space and having a heater, and configured to control temperature of the substrate; a plasma generator configured to generate plasma in the substrate processing space to perform ashing using the plasma as a substrate processing process; and a chuck temperature control unit configured to divide the substrate chuck into a plurality of heating areas and control temperature of the substrate chuck for each of the heating areas, wherein the chuck temperature control unit may include: a heat absorbing plate provided below the substrate chuck, an upper surface of which contacts a lower surface of the substrate chuck, and which absorbs heat conducted from the substrate chuck to adjust the temperature of the substrate chuck; a heat shielding plate provided on a lower surface of the heat absorbing plate; and a nozzle block configured to spray a cooling gas upward from below the heat shielding plate, wherein the heat absorbing plate may be composed of a plurality of heat absorbing blocks divided to absorb the heat by heating area, whereas the heat shielding plate may be composed of a plurality of heat shielding blocks divided to block heat transfer by the heating area, wherein the heat absorbing blocks and the heat shielding blocks may be selectively removed on the basis of temperature in each of the heating areas.

The technical solutions will become more specific and clearer through the embodiments and drawings described below. In addition, various solutions other than those mentioned below may be additionally presented.

According to an embodiment of the present disclosure, the temperature of a specific area of a substrate chuck with a heater can be easily adjusted using a heat absorbing plate, a heat shielding plate, and/or a nozzle block for spraying cooling gas. Therefore, the temperature deviation of the substrate chuck can be minimized, and furthermore, a substrate can be heated to an overall uniform temperature.

The advantageous effects are not limited to this, and other effects not mentioned can be clearly understood by those skilled in the art from the present specification and the attached drawings.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view showing the configuration of a substrate processing apparatus according to an embodiment of the present disclosure;

FIG. 2 is a perspective view showing a chuck temperature control unit shown in FIG. 1; and

FIGS. 3 to 5 are cross-sectional views showing the operation of a substrate processing apparatus according to an embodiment of the present disclosure.

### DETAILED DESCRIPTION OF THE INVENTION

Hereinafter, embodiments of the present disclosure will be described in detail with reference to the accompanying drawings so that those skilled in the art can easily carry out the present disclosure. However, the present disclosure may be embodied in many different forms and is not limited to the embodiments described herein.

In describing the embodiments of the present disclosure, when it is determined that a detailed description of a related known function or configuration may unnecessarily obscure the subject matter of the present disclosure, the specific description will be omitted, and parts with similar functions and actions will use the same reference numerals throughout the drawings.

Since at least some of the terms used in the specification are defined in consideration of functions in the present disclosure, they may vary according to user, operator intention, custom, and the like. Therefore, the terms should be interpreted based on the contents throughout the specification. In addition, in this specification, when a certain component is said to be included, this means that other components may also be included without excluding other components unless otherwise stated. When a part is said to be connected (or coupled) with another part, this includes not only the case of being directly connected (or coupled), but also the case of being indirectly connected (or coupled) with another part in between.

Meanwhile, in the drawings, the size or shape of components, and thickness of lines may be somewhat exaggerated for convenience of understanding.

A substrate processing apparatus according to the present disclosure may be used to perform various substrate processing processes. The embodiments of the present disclosure will be described mainly with reference to a substrate that is a circular wafer, and a substrate processing apparatus that performs ashing as a processing process for wafers.

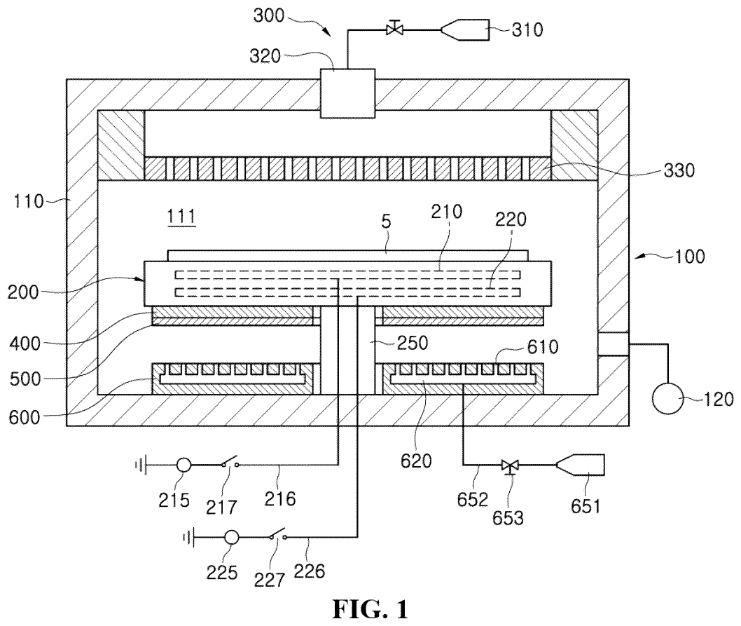

The configuration, operation, etc. of a substrate processing apparatus according to an embodiment of the present disclosure are shown in FIGS. 1 to 5.

A substrate processing apparatus according to an embodiment of the present disclosure is configured to perform an ashing process using plasma, thereby removing photoresist (PR) remaining on a substrate after an etching process.

Referring to FIG. 1, a substrate processing apparatus according to an embodiment of the present disclosure includes a process chamber 100, a substrate chuck 200, a process gas supply unit 300, and an electromagnetic field forming unit (plasma source). In order for a substrate processing process to be performed, the substrate chuck 200 supports a substrate 5. The process gas supply unit 300 supplies a process gas, and the electromagnetic field forming unit generates an electromagnetic field to excite the process gas into a plasma state.

The process chamber 100 is configured to have a substrate processing space 111 that may be blocked from the outside. The substrate 5 may be processed by plasma in the substrate processing space 111 when a substrate processing process is performed. The process chamber 100 includes a chamber body 110. The substrate processing space 111 is formed inside the chamber body 110.

The chamber body 110 substrate entrance 112 communicating with the substrate processing space 111. The substrate 5 to be processed is brought into the substrate processing space 111 within the chamber body 110 from the outside of the chamber body 110 through the substrate entrance 112. The processed substrate 5 is taken out from the substrate processing space 111 to the outside of the chamber body 110 through the substrate entrance 112. The substrate entrance 112 is opened and closed by an entrance opening/closing unit.

The chamber body 110 has an exhaust port that communicates with the substrate processing space 111. The exhaust port is provided on the wall of the chamber main body 110. An exhaust unit 120 that performs an exhaust function is connected to the exhaust port. Due to the exhaust function of the exhaust unit 120, the substrate processing space 111 may be depressurized. In addition, byproducts generated during the substrate processing process, gases remaining in the substrate processing space 111, etc. may be discharged to the outside.

The substrate chuck 200 is installed inside the chamber body 110. The substrate chuck 200 supports the substrate 5 in the substrate processing space 111. The substrate chuck 200 is disposed in the lower area of the substrate processing space 111. The substrate chuck 200 is spaced upward from the bottom of the substrate processing space 111 by a chuck support 250. The chuck support 250 supports the substrate chuck 200. The chuck support 250 may be provided to the substrate chuck 200 in a shape that protrudes downward from the central portion of the lower surface of the substrate chuck 200.

The substrate chuck 200 is formed in a disk shape with a predetermined thickness. The substrate chuck 200 includes a chuck electrode 210 and a heater 220.

The chuck electrode 210 is embedded in the substrate chuck 200. A chuck power source 215 is electrically connected to the chuck electrode 210 through a chuck power line 216. The chuck power source 215 includes a direct current power source. A chuck power switch 217 is applied between the chuck electrode 210 and the chuck power source 215. The chuck power switch 217 may be provided on the chuck power line 216. In addition, the chuck electrode 210 and the chuck power source 215 may be electrically connected to each other or released from each other by the on and off operations of the chuck power switch 217. When the chuck power switch 217 is turned on, an electrostatic force is generated between the substrate 5 and the chuck electrode 210. While a substrate processing process is being performed, the substrate 5 may be chucked to the substrate chuck 200 due to the electrostatic force thus generated. Depending on the implementation conditions, etc., the chuck electrode 210 and a chuck power supply module (chuck power source, chuck power line, and power switch) are excluded, and a type configured to mechanically chucking the substrate 5 may be applied as a chucking module replacing the chuck electrode 210 and the chuck power supply module.

The heater 220 is provided inside the substrate chuck 200. The heater 220 may be positioned below the chuck electrode 210. A heater power source 225 is electrically connected to the heater 220 through a heater power line 226. The heater 220 may be configured to generate high-temperature heat by resisting current from the heater power source 225. For example, the heater 220 may include a coil formed in a spiral shape. A heater power switch 227 is applied between the heater 220 and the heater power source 225. The heater power switch 227 may be provided on the heater power line 226. The heater 220 and the heater power source 225 may be electrically connected to each other or disconnected from each other by an on and off operation of the heater power switch 227. While a substrate processing process is performed, when the heater power switch 227 is turned on, heat is generated by the heater 220. The generated heat is provided throughout the substrate chuck 200 and transferred to the substrate 5 through the substrate chuck 200, and the substrate 5 may be maintained at a temperature required for the substrate processing process by the transferred heat.

The process gas supply unit 300 supplies a process gas required for a substrate processing process (ashing) to the substrate processing space 111 when the substrate processing process is performed. The process gas supply unit 300 may include a distribution head, a process gas supply source 310, a process gas supply nozzle 320, a process gas supply line, and a flow control valve.

The distribution head may be installed on the ceiling side of the chamber body 110 and may be arranged to face the substrate chuck 200. The distribution head includes a distribution plate 330 having process gas discharge holes through which a process gas is discharged downward, and is configured to have a buffer space provided for introducing a process gas above the distribution plate 330 and communicating with the process gas discharge holes. The distribution plate 330 is made of metal, is electrically connected to a high-frequency power source, or is grounded so as to function as an upper electrode constituting the electromagnetic field forming unit.

The process gas supply source 310 may be connected to the process gas supply nozzle 320 through the process gas supply line and may provide process gas to the process gas supply nozzle 320 at a predetermined pressure. The process gas supply nozzle 320 is installed on the ceiling of the chamber body 110 and is connected to the distribution head to supply process gas to the buffer space within the distribution head. The process gas may be discharged and distributed from the buffer space to the substrate processing space 111 through the process gas discharge holes of the distribution plate 330. The flow control valve may be provided on the process gas supply line. The flow rate of the process gas supplied to the shower head through the process gas supply line and the process gas supply nozzle 320 may be controlled by the flow control valve.

The electromagnetic field forming unit constitutes a plasma generator together with the process gas supply unit 300. The electromagnetic field forming unit may be configured to generate plasma in a CCP (capacitively coupled plasma) manner by including an upper electrode and a lower electrode disposed to face each other vertically. As described, the upper electrode may be provided as the distribution plate 330. For example, the lower electrode may be provided at the bottom of the chamber body 110. Alternatively, the electromagnetic field forming unit may be configured to generate plasma in an ICP (inductively coupled plasma) manner, and may include an antenna for this purpose.

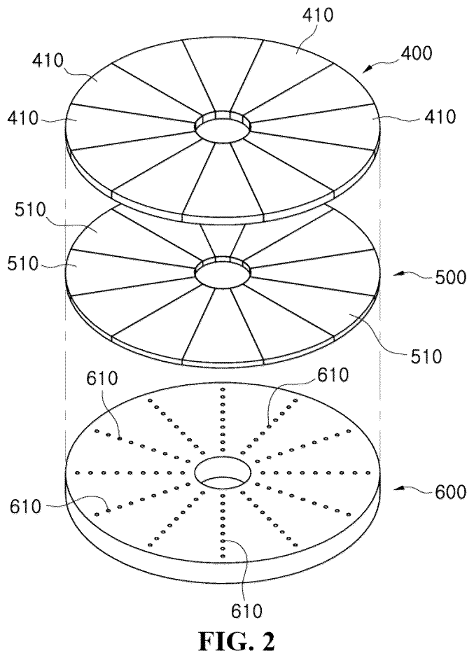

The substrate processing apparatus according to an embodiment of the present disclosure further includes a chuck temperature control unit. The construction and operation of the chuck temperature control unit is shown in FIGS. 2 to 5. Referring to FIGS. 1 and 2, the chuck temperature control unit includes a heat absorbing plate 400, a heat shielding plate 500, and a nozzle block 600. According to the chuck temperature control unit, the temperature of the substrate chuck 200 may be adjusted for each region of the substrate chuck 200.

The heat absorbing plate 400 is provided below the substrate chuck 200. The heat absorbing plate 400 has the upper surface thereof in contact with the lower surface of the substrate chuck 200 and is formed in a shape corresponding to the lower surface of the substrate chuck 200. Since the upper surface of the heat absorbing plate 400 is in contact with the lower surface of the substrate chuck 200, the temperature of the substrate chuck 200 may be adjusted as the heat absorbing plate 400 absorbs heat conducted from the substrate chuck 200 when a substrate processing process is performed. The heat absorbing plate 400 may emit absorbed heat to lower the temperature of the substrate chuck 200. The heat absorbing plate 400 may include a material with excellent heat conductivity. For example, the heat absorbing plate 400 may be a heat sink made of aluminum. In this case, the aluminum may be aluminum nitride (AIN).

The heat absorbing plate 400 is composed of a plurality of heat absorbing blocks 410 divided to absorb heat from the substrate chuck 200 for each heating area by dividing the substrate chuck 200 into a plurality of heating areas. Referring to FIG. 2, the heating areas are set to be arranged along the circumferential direction, and the heat absorbing plate 400 may be divided so that the heat absorbing blocks 410 are arranged along the circumferential direction corresponding to the set heating areas. The divided form of the heat absorbing plate 400 is not limited to this and may be modified in various ways.

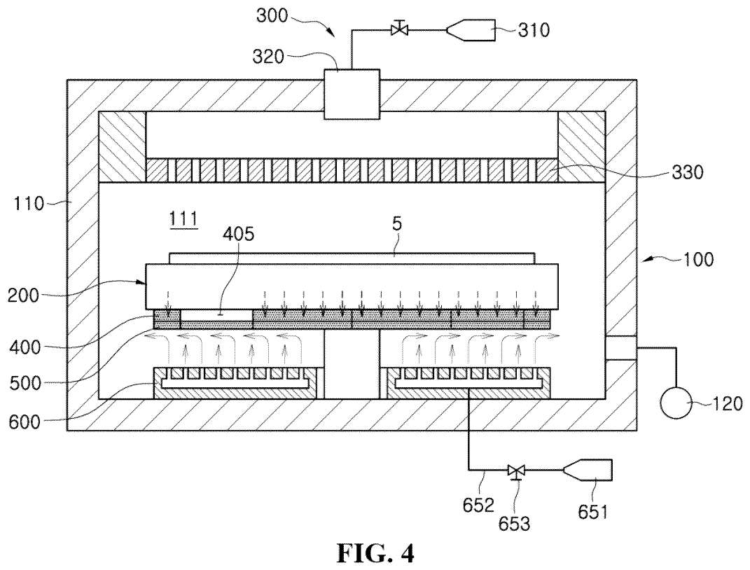

The heat absorbing blocks 410 may be selectively removed on the basis of the temperature of each set heating area. That is, on the basis of the temperature for each set heating area, one or more selected heat absorbing blocks 410 may be removed. The temperature of the heating area (see reference numeral 405 in FIG. 4) from which the heat absorbing block 410 is removed may increase because the heat absorption effect of the heat absorbing block 410 on conducted heat is not directly applied.

The heat shielding plate 500 is disposed below the heat absorbing plate 400. The heat shielding plate 500 is provided on the lower surface of the heat absorbing plate 400 and is formed in a shape corresponding to the lower surface of the substrate chuck 200 in the same or similar manner as the heat absorbing plate 400. The heat shielding plate 500 may prevent the temperature of the substrate chuck 200 from dropping excessively by suppressing the rapid dissipation of heat absorbed by the heat absorbing plate 400 through a heat transfer blocking function. The heat shielding plate 500 may include a material with excellent thermal barrier properties.

Referring to FIG. 2, the heat shielding plate 500 is composed of a plurality of heat shielding blocks 510 divided to block heat transfer for each set heating area.

The nozzle block 600 is provided on the bottom side of the substrate processing space 111, is spaced downward from the heat shielding plate 500, and is arranged to face the heat shielding plate 500. The nozzle block 600 sprays cooling gas upward toward the heat shielding plate 500. For this purpose, nozzle holes 610 are formed throughout the upper surface of the nozzle block 600. The nozzle block 600 is formed in a shape corresponding to the lower surface of the substrate chuck 200 in the same or similar manner as the heat shielding plate 500.

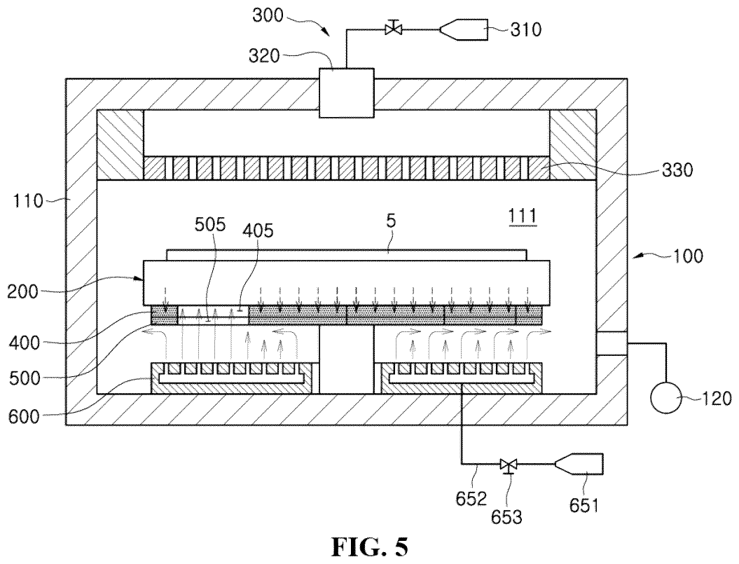

The heat shielding blocks 510 may be selectively removed on the basis of the temperature of each set heating area. That is, on the basis of the temperature for each set heating area, one or more selected heat shielding blocks 510 may be removed. The temperature of the heating area (see reference numeral 505 in FIG. 5) from which the heat shielding block 510 is removed may decrease because cooling gas is supplied from the nozzle block 600.

Referring to FIG. 1, the nozzle block 600 may receive an inert gas (e.g., nitrogen) as a cooling gas from a gas supply module and spray the gas. The gas supply module includes a cooler (not shown), a cooling gas supply source 651, a cooling gas supply line 652, and an on/off valve 653.

The cooler cools the cooling gas to a set temperature. The cooler is provided to the cooling gas supply source 651 to cool the cooling gas in the cooling gas supply source 651, or is provided on the cooling gas supply line 652 to cool the cooling gas flowing along the cooling gas supply line 652. The cooling gas supply source 651 is connected to the nozzle block 600 through the cooling gas supply line 652. The cooling gas supply source 651 may be configured to provide a storage space in which the cooling gas is stored therein and to provide the stored cooling gas to the nozzle block 600 at a set pressure through the cooling gas supply line 652. The on/off valve 653 of the nozzle block 600 is provided on the cooling gas supply line 652, and thus may open and close the cooling gas supply line 652, and may control the flow rate of the cooling gas flowing along the cooling gas supply line 652.

The cooling gas sprayed upward from the nozzle block 600 may collide with the lower surface of the heat shielding plate 500 and change the flow direction to the side wall of the chamber body 110. The exhaust port may be placed at a height that enables smooth discharge of the cooling gas toward the side wall of the chamber body 110. The cooling gas directed toward the side wall of the chamber body 110 and discharged through the exhaust port induces the by-products generated during a substrate processing process to be discharged through the exhaust port, thereby preventing the by-products from accumulating on the bottom of the substrate processing space 111.

Although not shown, the substrate processing apparatus according to an embodiment of the present disclosure further includes a chuck temperature detector that detects the temperature for each set heating area. For example, the chuck temperature detector may include a thermocouple.

Due to the chuck temperature detector, the temperature distribution of the substrate chuck 200 may be determined through the temperature detected for each set heating area.

When there is a heating area where the temperature is relatively low and causes a temperature deviation in the substrate chuck 200 among the set heating areas, by removing the heat absorbing block 410 that absorbs heat from the relatively low temperature heating area, and in turn increasing the temperature of the relatively low temperature heating area (see FIG. 4), the temperature distribution of the substrate chuck 200 may be maintained uniformly.

On the other hand, when there is a heating area where the temperature is relatively high and causes a temperature deviation in the substrate chuck 200 among the set heating areas, by removing the heat absorbing block 410, which absorbs heat from the relatively high temperature heating area, and the corresponding heat shielding block 510, and by cooling the relatively high temperature heating area with cooling gas and lowering the temperature (see FIG. 5), the temperature distribution of the substrate chuck 200 may be maintained uniformly.

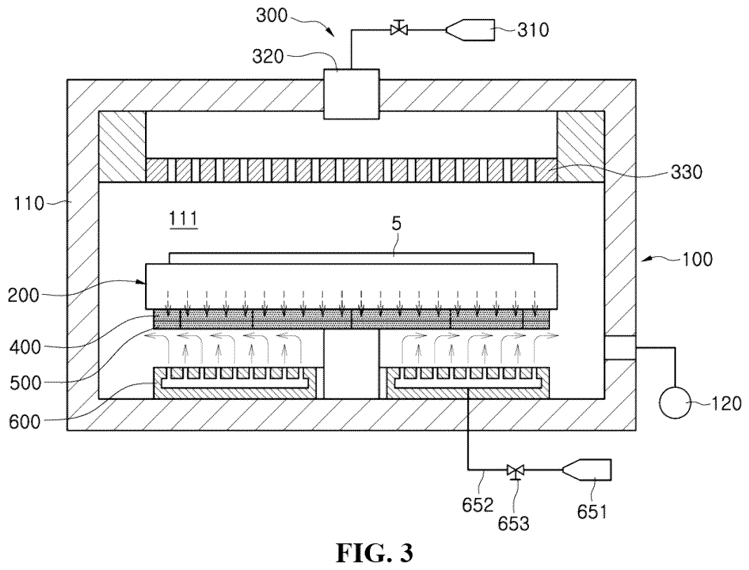

Meanwhile, when there is no heating area that causes a temperature deviation in the substrate chuck 200 among the set heating areas, the chuck temperature control unit may be operated with the nozzle block 600 operated and without the heat absorbing blocks 410 and the heat shielding blocks 510 being removed as shown in FIG. 3.

Although the present disclosure has been described above, the present disclosure is not limited to the disclosed embodiments and the accompanying drawings, and various modifications may be made by those skilled in the art without departing from the technical spirit of the present disclosure. In addition, the technical ideas described in the embodiments of the present disclosure may be implemented independently or in combination of two or more.

### DESCRIPTION OF NUMERALS

100: process chamber
110: chamber body
111: substrate processing space
120: exhaust unit
200: substrate chuck
220: heater
300: process gas supply unit
400: heat absorbing plate
500: heat shielding plate
600: nozzle block

What is claimed is:

1. A substrate processing apparatus, comprising:
a process chamber configured to provide a substrate processing space;
a substrate chuck configured to support a substrate in the substrate processing space, have a heater, and control temperature of the substrate; and
a heat absorbing plate provided on a lower surface of the substrate chuck and configured to adjust temperature of the substrate chuck by absorbing heat from the substrate chuck,
wherein the heat absorbing plate is composed of a plurality of heat absorbing blocks divided to absorb the heat by a plurality of heating areas,
wherein the substrate chuck is divided into the plurality of heating areas, and
wherein the plurality of heat absorbing blocks are selectively removed on a basis of a temperature of each of the plurality of heating areas.

2. The apparatus of claim 1, further comprising:
a heat shielding plate provided on a lower surface of the heat absorbing plate,
wherein the heat shielding plate is composed of a plurality of heat shielding blocks divided to block heat transfer by the plurality of heating areas, and
wherein the plurality of heat shielding blocks are selectively removed on the basis of the temperature of each of the plurality of heating areas.

3. The apparatus of claim 2, further comprising:
a nozzle block configured to spray a cooling gas upward from below the heat shielding plate.

4. The apparatus of claim 3,
wherein the substrate chuck is spaced upward from a bottom of the substrate processing space, and the nozzle block is disposed on a bottom side of the substrate processing space.

5. The apparatus of claim 3,
wherein the cooling gas sprayed upward from the nozzle block collides with a lower surface of the heat shielding plate and flows to a side wall of the process chamber, and the process chamber is provided with an exhaust port on a side wall thereof.

6. The apparatus of claim 3,
wherein the cooling gas is an inert gas.

7. The apparatus of claim 1, further comprising:
a chuck temperature detector configured to detect the temperature for each of the plurality of heating areas.

8. The apparatus of claim 1,
wherein the plurality of heat absorbing blocks is a heat sink.

9. The apparatus of claim 1,
wherein the substrate processing apparatus performs ashing as a substrate processing process.

10. A substrate processing apparatus, comprising:
a process chamber configured to provide a substrate processing space;
a substrate chuck configured to support a substrate in the substrate processing space, have a heater, and control temperature of the substrate; and
a chuck temperature control unit configured to divide the substrate chuck into a plurality of heating areas and adjust temperature of the substrate chuck for each of the plurality of heating areas using a temperature control gas.

11. The apparatus of claim 10,
wherein the chuck temperature control unit comprises a nozzle block configured to spray the temperature control gas upward from below the substrate chuck, and
wherein the nozzle block is configured to spray the temperature control gas for each of the plurality of heating areas.

12. The apparatus of claim 11,
wherein the nozzle block receives the temperature control gas from a gas supply module and sprays the received temperature control gas, and
wherein the gas supply module comprises a heater for heating the temperature control gas and a cooler for cooling the temperature control gas, and supplies the temperature control gas heated by the heater or supplies the temperature control gas cooled by the cooler on a basis of a temperature of each of the plurality of heating areas.

13. The apparatus of claim 10,
wherein the temperature control gas is a cooling gas.

14. The apparatus of claim 13,
wherein the chuck temperature control unit comprises:
a heat shielding plate provided below the substrate chuck; and
a nozzle block configured to spray the cooling gas upward from below the heat shielding plate,
wherein the heat shielding plate is composed of a plurality of heat shielding blocks divided to block heat transfer by the plurality of heating areas, and
wherein the plurality of heat shielding blocks are selectively removed on a basis of temperature of each of the plurality of heating areas.

15. The apparatus of claim 10,
wherein the temperature control gas is nitrogen.

16. The apparatus of claim 10, further comprising:
a chuck temperature detector configured to detect a temperature for each of the plurality of heating areas.

17. The apparatus of claim 10,
wherein the substrate processing apparatus performs ashing as a substrate processing process.

18. The apparatus of claim 14,
wherein the cooling gas sprayed upward from the nozzle block collides with a lower surface of the heat shielding plate and flows to a side wall of the process chamber, and the process chamber is provided with an exhaust port on a side wall thereof.

19. The apparatus of claim 1,
wherein the plurality of heat absorbing blocks are in contact with the lower surface of the substrate chuck to absorb the heat conducted from the substrate chuck.

20. A substrate processing apparatus, comprising:
a process chamber configured to provide a substrate processing space;
a substrate chuck configured to support a substrate in the substrate processing space, spaced upward from a bottom of the substrate processing space and having a heater, and configured to control temperature of the substrate;
a plasma generator configured to generate plasma in the substrate processing space to perform ashing using the plasma as a substrate processing process; and
a chuck temperature control unit configured to divide the substrate chuck into a plurality of heating areas and control temperature of the substrate chuck for each of the plurality of heating areas,
wherein the chuck temperature control unit comprises:
a heat absorbing plate provided below the substrate chuck, an upper surface of which contacts a lower surface of the substrate chuck, and which absorbs heat conducted from the substrate chuck to adjust the temperature of the substrate chuck;
a heat shielding plate provided on a lower surface of the heat absorbing plate; and
a nozzle block configured to spray a cooling gas upward from below the heat shielding plate,
wherein the heat absorbing plate is composed of a plurality of heat absorbing blocks divided to absorb the heat by heating area, whereas the heat shielding plate is composed of a plurality of heat shielding blocks divided to block heat transfer by the heating area, and
wherein the plurality of heat absorbing blocks and the plurality of heat shielding blocks are selectively removed on a basis of temperature in each of the plurality of heating areas.
